(19) United States
(12) Patent Application Publication
(10) Pub. No.: US 2003/0141560 A1
(43) Pub. Date: Jul. 31, 2003

(54) Incorporating TCS-SiN barrier layer in dual gate CMOS devices

(76) Inventor: Shi-Chung Sun, Taipei (TW)

Correspondence Address: BIRCH STEWART KOLASCH & BIRCH, PO BOX 747, FALLS CHURCH, VA, 22040-0747, US

(21) Appl. No.: 10/054,824

(22) Filed: Jan. 25, 2002

(51) Int. Cl. H01L 21/8238; H01L 21/31; H01L 21/469; H01L 27/108; H01L 29/76; H01L 29/94; H01L 31/119

(52) U.S. Cl. 257/410; 438/199; 438/761; 438/793; 257/369; 257/310; 257/389; 257/406; 257/407; 257/411

(57) ABSTRACT

A method of forming a diffusion barrier layer in a semiconductor device is disclosed. A high-k gate dielectric layer is formed over a substrate. A silicon nitride barrier layer is subsequently formed over the high-k gate dielectric layer by reacting tetrachlorosilane with ammonia through a chemical vapor deposition process. The silicon nitride barrier layer substantially blocks diffusion of impurities from an ensuing overlying gate layer. A semiconductor device comprising the silicon nitride barrier layer, and a method of fabricating such a semiconductor device are also disclosed.

### BACKGROUND OF THE INVENTION

1. Field of the Invention

The present invention relates in general to the fabrication of MOSFET devices. More specifically, the present invention relates to forming a diffusion barrier layer that is particularly suitable for use in dual gate CMOS devices that require boron-doped gate electrodes in the pMOS part.

2. Description of the Related Arts

An integrated circuit that employs both nMOS and pMOS devices is generally known as a complementary MOS or CMOS circuit. In a conventional CMOS device, the gate electrode is doped with phosphorous to form the n⁺ gate for both nMOS and pMOS sides. For smaller channel lengths, i.e., 0.25 μm and below, it is necessary to form p⁺ doped polysilicon gates using boron for the pMOS side to minimize short channel effects. Thus, a CMOS device comprised of a p-channel MOS transistor having a p-type gate electrode and an n-channel MOS transistor having an n-type gate electrode is called a dual gate construction CMOS.

High dielectric constant (high-k) dielectrics such as ZrO₂, HfO₂, Al₂O₃ and the like have been proposed as a potential gate dielectric for solving scaling problems of conventional thermal oxide gate dielectrics at 70 nm generation node and below. A difficulty associated with dual gate CMOS devices using high-k gate dielectrics is boron penetration. In the pMOS side, boron is found to diffuse from the gate electrode through the high-k dielectric and into the channel region during heat treatment. Boron penetration into the channel results in a decrease in low-field hole mobility and degradation of threshold voltage (Vt). The present invention therefore aims to achieve realization of dual gate CMOS devices using high-k gate dielectrics without boron penetration.

### SUMMARY OF THE INVENTION

An object of the invention is to provide a method of forming a diffusion barrier layer in a semiconductor device to provide protection against boron penetration.

Another object of the invention is to provide a method of fabricating a semiconductor device with enhanced resistance to degradations of threshold voltage and low-field hole mobility.

A further object of the invention is to provide a semiconductor device that incorporates a diffusion barrier layer in the gate stack such that the diffusion barrier layer blocks diffusion of impurities from the gate electrode.

The above and other objects are accomplished by inserting a tetrachlorosilane-based silicon nitride (TCS-based SiN) layer between the gate electrode and the high-k gate dielectric. The TCS-based SiN layer serves to inhibit diffusion of boron or other impurities from the gate electrode into the substrate. Further, the TCS-based SiN does not appreciably release hydrogen during high-temperature processing as does the conventional dichlorosilane-based silicon nitride (DCS-based SiN).

According to an aspect of the invention, there is provided a method of forming a diffusion barrier layer in a semiconductor device, which comprises the steps of: forming a high-k gate dielectric layer over a substrate; forming a silicon nitride barrier layer over the high-k gate dielectric layer by reacting tetrachlorosilane with ammonia through a chemical vapor deposition process, whereby the silicon nitride barrier layer blocks diffusion of impurities from a subsequently formed gate layer.

According to another aspect of the invention, there is provided a method of fabricating a semiconductor device on a substrate, comprising the steps of: forming a high-k gate dielectric layer over the substrate; forming a silicon nitride barrier layer by reacting tetrachlorosilane with ammonia through a chemical vapor deposition process; forming a gate electrode layer over the silicon nitride barrier layer; patterning the high-k gate dielectric layer, the silicon nitride barrier layer, and the gate electrode layer to form a gate structure; and forming source and drain regions in the substrate by ion implantation.

According to a further aspect of the invention, there is provided a semiconductor device, which comprises a silicon nitride barrier layer interposed between a gate electrode and a high-k gate dielectric, wherein the silicon nitride barrier layer is formed by reacting tetrachlorosilane with ammonia through a chemical vapor deposition process, whereby the silicon nitride barrier layer blocks diffusion of impurities from the gate electrode.

### BRIEF DESCRIPTION OF THE DRAWINGS

The above and other objects, features, and advantages of the present invention will become apparent from the following detailed description of preferred embodiments of the invention explained with reference to the accompanying drawings, in which:

FIGS. 1 through 5 are cross-sections illustrating the steps for fabricating a pMOS transistor according to a preferred embodiment of the invention;

FIG. 6 depicts the concentration of SiH bonds in a DCS-based SiN film as a function of the annealing temperature;

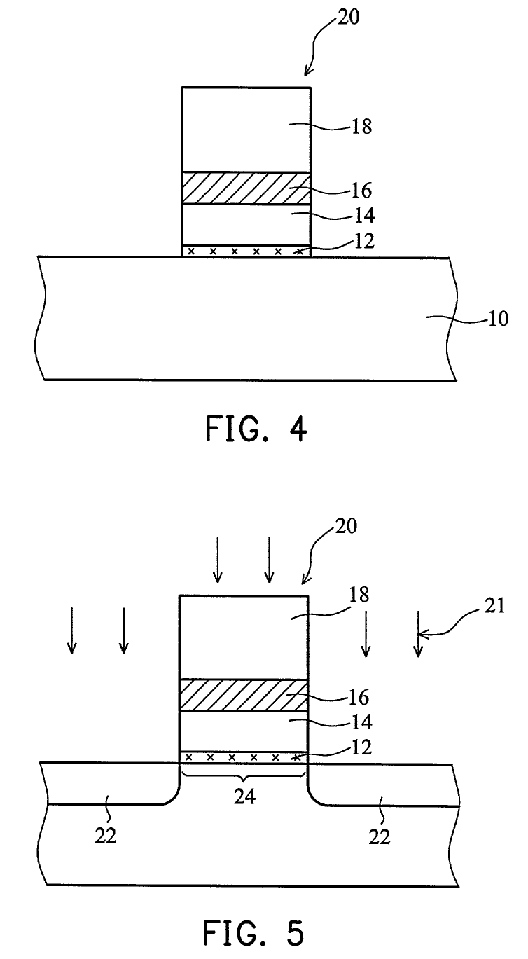

FIG. 7 depicts the concentration of NH bonds in a TCS-based SiN film as a function of the annealing temperature; and

FIG. 8 illustrates a dual gate CMOS device which incorporates a TCS-based SiN barrier layer in the gate stacks.

### REFERENCE NUMERALS IN THE DRAWINGS

2 CMOS device

4 p-well

6 n-well

8 trench isolation

10 semiconductor substrate

12 nitrided layer

14 high-k dielectric layer

16 TCS-based SiN layer

18 gate electrode layer

20 gate structure

21 ion implantation

22 source/drain regions

### DESCRIPTION OF THE PREFERRED EMBODIMENTS

The following embodiment will be described in the context of a pMOS part of a dual gate CMOS device. However, the skilled artisan will appreciate that the transistor may be implemented as a nMOS part of the CMOS device, provided that appropriate changes of the doping polarity or conductivity type are applied.

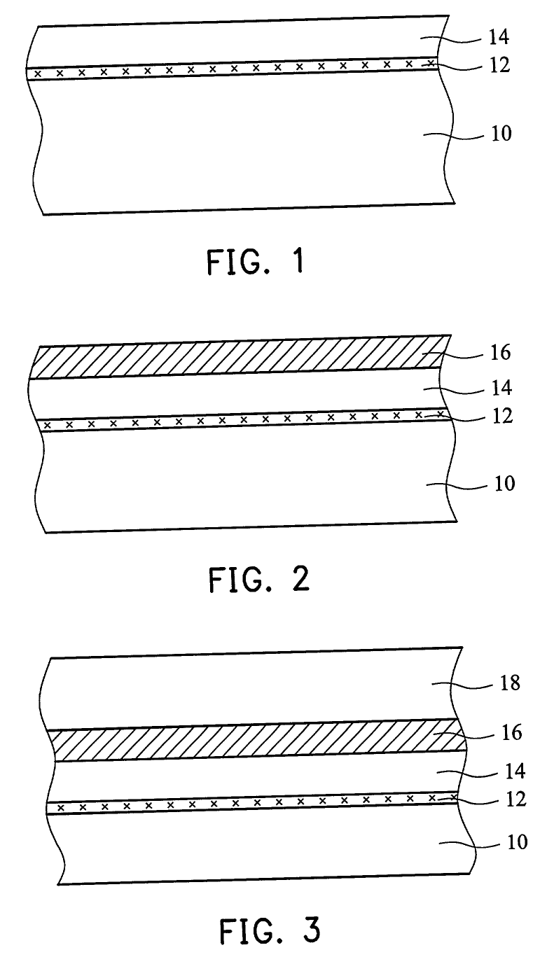

Referring to FIG. 1, a partial cross-section of a semiconductor substrate 10 is depicted. The substrate 10 comprises single crystalline silicon which has been slightly doped with n-type impurities. A thin nitrided layer 12 having a thickness of about 3 to 10 Å is optionally formed on the substrate 10 by annealing under ambient of ammonia (NH₃) or nitric oxide (NO). The nitrided layer 12 will generally be a silicon nitride or silicon oxynitride.

Thereafter, a gate dielectric layer 14 having a desirable thickness of about 20 to 200 Å is formed by depositing a high-k dielectric material on the nitrided layer 12. The high-k layer 14 may have a k value of about 8 to 1,000 and may be formed from such materials as metal oxides or silicates. Exemplary metal oxides include ZrO₂, HfO₂, Al₂O₃, TiO₂, and Ta₂O₅. Exemplary silicates include ZrSiO₄ and HfSiO₄. The high-k layer 14 may be deposited by low pressure chemical vapor deposition (CVD), metal organic CVD, jet vapor deposition, sputter deposition or like techniques. In an exemplary embodiment, the layer 14 is formed by depositing a metal film followed by annealing in an oxygen containing ambient.

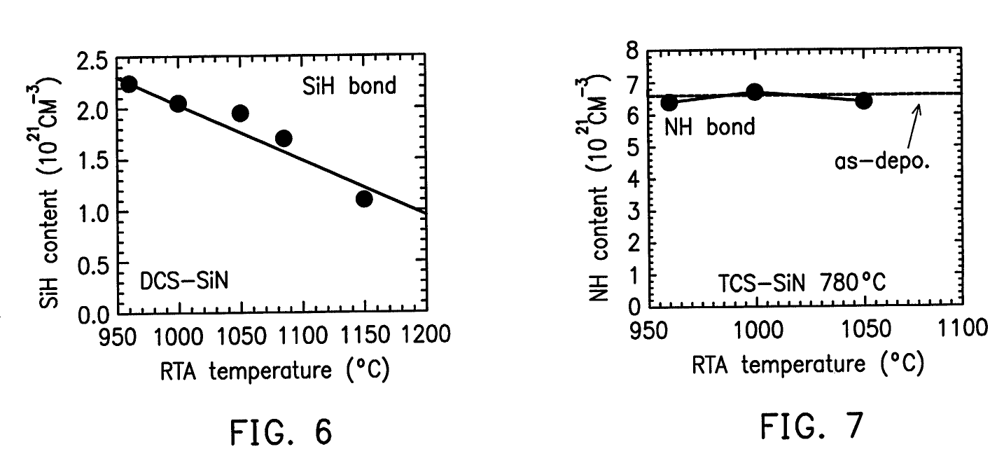

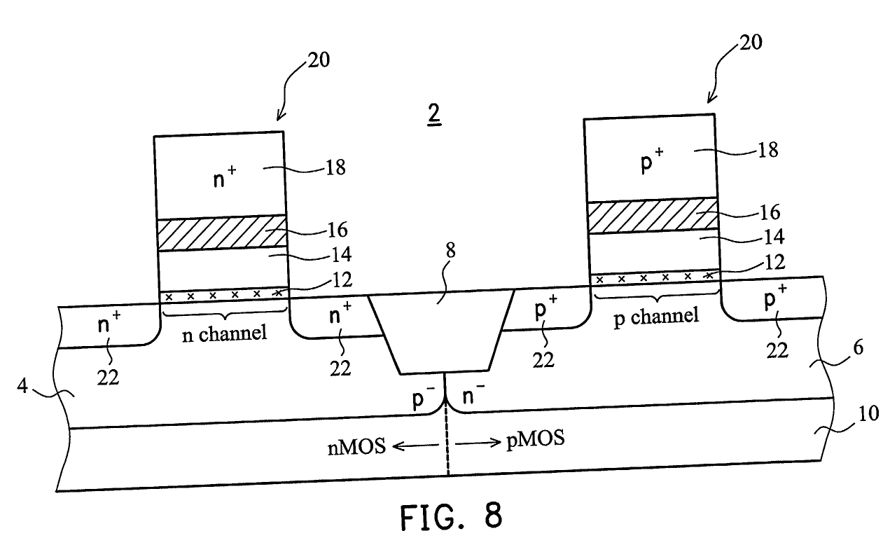

Following the formation of the gate dielectric 14, referring to FIG. 2, a relatively thin layer of silicon nitride 16 having a desirable thickness of about 5 to 20 Å is deposited prior to deposition of a gate electrode layer. The silicon nitride layer 16 may subsequently serve as a barrier layer that substantially inhibits dopant (e.g., boron, phosphorus, or arsenic) penetration into the substrate 10. According to an important feature of the present invention, the silicon nitride is deposited through a chemical vapor deposition process by reacting tetrachlorosilane (SiCl₄) with ammonia (NH₃) (hereafter referred to as “TCS-based SiN”). The TCS-based SiN is thermally more stable compared to the silicon nitride formed by reacting dichlorosilane (SiH₂Cl₂) with ammonia (NH₃) in conventional methods (hereafter referred to as “DCS-based SiN”). As illustrated in FIGS. 7 and 8, the DCS-based SiN comprises Si—H bonds which release hydrogen at high temperatures and will thereby, enhance boron penetration. In contrast, the TCS-based SiN comprises N-H bonds which are stable up to 1050° C. No release of hydrogen will occur to the TCS-based SiN during the subsequent high-temperature processing. In an exemplary embodiment, the TCS-based SiN layer 16 is formed by a low pressure chemical vapor deposition (LPCVD) process at a temperature ranging from about 725° C. to 825° C.

Referring now to FIG. 3, a conductive layer 18 is formed overlying the SiN layer 16 to function as a gate electrode of an MOS transistor. The layer 18 may be composed of a variety of conductive materials and is preferably polysilicon. Well known techniques for applying polysilicon such as CVD, may be used to deposit the layer 18. In an exemplary embodiment, the polysilicon is deposited at or above 625° C. to a thickness of about 750 to 1,800 Å. Later implants for the source/drain regions will render the layer 18 conductive.

In FIG. 4, the layers 18, 16, 14, 12 are patterned via etching to define a gate structure 20, by reactive ion etching, chemical plasma etching, or other like anisotropic etching techniques.

In FIG. 5, an ion implantation, as represented by arrows 21, is applied to create source and drain regions 22. The gate electrode layer 18 is made conductive at the same time. In this embodiment, a p-type dopant such as boron or boron difluoride is implanted to form a pMOS transistor. If a nMOS transistor is desired, an n-type dopant such as arsenic or phosphorus may be implanted. The gate structure 20 provides an implant mask for the underlying portion of the substrate 10. The lateral separation of the source/drain regions 22 defines the channel region 24 beneath the gate structure 20. Desirably, the implant has a dosage in the range of 5×10¹⁴ to 5×10¹⁵ atoms/cm², and an energy level ranging between 2 to 80 keV.

Activation of the source/drain region 22 may conincide with one or more of the various high temperature steps that normally accompany metallization. However, the source/drain regions 22 may be annealed at this stage, if desired. For example, the anneal may be a rapid thermal annealing (RTA) at about 900 to 1075° C. for about 30 to 60 seconds, and in an inert ambient of argon, helium, or nitrogen.

During the above-mentioned high temperature steps, dopants such as boron or other impurities within the gate electrode 18 may diffuse through the high-k gate dielectric 14 and into the channel region 24. However, the TCS-based SiN layer 16 between the gate electrode 18 and the high-k gate dielectric 14 substantially block the diffusion pathways so that the dopants cannot pass into the substrate.

The process in accordance with the above embodiment yields a pMOS transistor having a high-k gate dielectric that is not susceptible to boron penetration. Accordingly, the present invention is particularly useful in making dual gate CMOS devices that require boron-doped gate electrodes in the pMOS part.

An exemplary embodiment of a dual gate CMOS device incorporating the TCS-based SiN barrier layer according to the invention is illustrated in FIG. 8. Parts of configuration similar to those of the embodiment illustrated in FIGS. 1-5 are given the same reference numeral and are not explained further. The CMOS device 2 is formed with wells acting as functional regions of the nMOS transistors and the pMOS transistors. In the illustrated embodiment, the surface of the semiconductor substrate 10 is formed with the p-well 4 and the n-well 6 with different conductivities from each other as so-called “twin tub” functional regions. Note that the construction of the wells is not limited to the ones illustrated. At the interface of the two transistor regions is formed a trench isolation 8 to achieve separation of the transistor regions. In this dual gate COMS device 2, the gate electrode of the MOS transistor is of the same type as the channel. Therefore, the gate electrode 18 in the pMOS part is doped with boron or other p-type impurities. The gate electrode 18 in the nMOS part is doped with phosphorous, arsenic, or other n-type impurities. The TCS-based SiN layer 16 provided in the gate stack 20 prevents the impurities, especially boron, from penetrating into the channel region.

While the invention has been particularly shown and described with reference to the preferred embodiment thereof, it will be understood by those skilled in the art that various changes in form and details may be made without departing from the spirit and scope of the invention.

What is claimed is:

1. A method of forming a diffusion barrier layer in a semiconductor device, comprising the steps of:
forming a high-k gate dielectric layer over a substrate;
forming a silicon nitride barrier layer over the high-k gate dielectric layer by reacting tetrachlorosilane with ammonia through a chemical vapor deposition process, whereby the silicon nitride barrier layer blocks diffusion of impurities from a subsequently formed gate layer.

2. The method as claimed in claim 1, wherein the high-k gate dielectric layer has a k value between about 8 to 1,000.

3. The method as claimed in claim 1, wherein the high-k gate dielectric layer is selected from the group consisting of metal oxides and silicates.

4. The method as claimed in claim 1, wherein the silicon nitride barrier layer has a thickness of about 5 to 20 Å.

5. The method as claimed in claim 1, wherein the silicon nitride barrier layer is formed by a low pressure chemical vapor deposition (LPCVD) process at a temperature between about 725° C. to 825° C.

6. The method as claimed in claim 1, further comprising forming a nitrided layer over the substrate prior to forming the high-k gate dielectric layer.

7. A method of fabricating a semiconductor device on a substrate, comprising the steps of:
forming a high-k gate dielectric layer over the substrate;
forming a silicon nitride barrier layer by reacting tetrachlorosilane with ammonia through a chemical vapor deposition process;
forming a gate electrode layer over the silicon nitride barrier layer;
patterning the high-k gate dielectric layer, the silicon nitride barrier layer, and the gate electrode layer to form a gate structure; and
forming source and drain regions in the substrate by ion implantation.

8. The method as claimed in claim 7, wherein the high-k gate dielectric layer has a k value between about 8 and 1,000.

9. The method as claimed in claim 7, wherein the high-k gate dielectric layer is selected from the group consisting of metal oxides and silicates.

10. The method as claimed in claim 7, wherein the silicon nitride barrier layer has a thickness of about 5 to 20 Å.

11. The method as claimed in claim 7, wherein the silicon nitride barrier layer is formed by a low pressure chemical vapor deposition (LPCVD) process at a temperature between about 725° C. to 825° C.

12. The method as claimed in claim 7, further comprising forming a nitrided layer over the substrate prior to forming the high-k gate dielectric layer.

13. The method as claimed in claim 7, wherein the semiconductor device is a pMOS transistor having a p-type gate electrode.

14. The method as claimed in claim 13, wherein the ion implantation is performed by implanting boron or boron difluoride.

15. The method as claimed in claim 7, wherein the semiconductor device is a nMOS transistor having a n-type gate electrode.

16. The method as claimed in claim 15, wherein the ion implantation is performed by implanting arsenic or phosphorous.

17. The method as claimed in claim 7, wherein the semiconductor device is a CMOS device comprised of a pMOS transistor having a p-type gate electrode and a nMOS transistor having a n-type gate electrode.

18. A semiconductor device comprising a silicon nitride barrier layer interposed between a gate electrode and a high-k gate dielectric, wherein the silicon nitride barrier layer is formed by reacting tetrachlorosilane with ammonia through a chemical vapor deposition process, whereby the silicon nitride barrier layer blocks diffusion of impurities from the gate electrode.

19. The method as claimed in claim 18, wherein the high-k gate dielectric has a k value between about 8 and 1,000.

20. The method as claimed in claim 18, wherein the high-k gate dielectric is selected from the group consisting of metal oxides and silicates.

21. The method as claimed in claim 18, wherein the silicon nitride barrier layer has a thickness of about 5 to 20 Å.

22. The method as claimed in claim 18, wherein the silicon nitride barrier layer is formed by a low pressure chemical vapor deposition (LPCVD) process at a temperature between about 725° C. to 825° C.

23. The method as claimed in claim 18, wherein the semiconductor device is a pMOS transistor having a p-type gate electrode.

24. The method as claimed in claim 18, wherein the semiconductor device is a nMOS transistor having a n-type gate electrode.

25. The method as claimed in claim 18, wherein the semiconductor device is a CMOS device comprised of a pMOS transistor having a p-type gate electrode and a nMOS transistor having a n-type gate electrode.
